(19) United States
(12) Patent Application Publication
(10) Pub. No.: US 2026/0130055 A1
(43) Pub. Date: May 7, 2026

(54) DISPLAY APPARATUS AND METHOD OF MANUFACTURING THE SAME

(71) Applicant: LG Display Co., Ltd., Seoul (KR)

(72) Inventors: Gyu Hyeong HAN, Paju-si (KR); Hun Bae IM, Paju-si (KR); Yoon Seok LEE, Paju-si (KR); Eon Ho CHA, Paju-si (KR); Eun Sol JEON, Paju-si (KR); Sang Bin SHIN, Paju-si (KR); Dae Hee HAN, Paju-si (KR)

(73) Assignee: LG Display Co., Ltd., Seoul (KR)

(21) Appl. No.: 19/328,839

(22) Filed: Sep. 15, 2025

(30) Foreign Application Priority Data
Nov. 4, 2024 (KR) 10-2024-0154452

(51) Int. Cl. H10K 59/122; H10K 59/12; H10K 59/80

(52) U.S. Cl. CPC H10K 59/122; H10K 59/1201; H10K 59/80521; H10K 59/873

(57) ABSTRACT

A display apparatus and a manufacturing method thereof capable of preventing or suppressing a cathode lifting phenomenon from occurring upon removal of a temporary protective film are disclosed. The display apparatus includes a substrate including active and non-active areas, a thin film transistor on the substrate in the active area, a planarization layer in the active area on the thin film transistor and in the non-active area and having a first contact hole on the thin film transistor, a bank layer disposed in the active and non-active areas on the planarization layer and having an open region in an emission area, a light emitting element disposed on the planarization layer to be connected to the thin film transistor through the first contact hole, and an organic insulating layer pattern disposed on the bank layer in the non-active area to cover an end of a cathode of the light emitting element.

This application claims the benefit of Korean Patent Application No. 10-2024-0154452, filed on Nov. 4, 2024, which is hereby incorporated by reference as if fully set forth herein.

### BACKGROUND

### Field of the Disclosure

The present disclosure relates to a display apparatus, and more particularly to a display apparatus and a method of manufacturing the same which are capable of preventing or suppressing a cathode lifting phenomenon from occurring upon removal of a temporary protective film.

### Discussion of the Related Art

Image display apparatuses, which render a variety of information on a screen, are core technologies of the information communication age, and are being developed toward further thinness, further lightness, greater portability, and higher performance. As such, display apparatuses, which may be manufactured to have a light and thin structure, are being highlighted.

As concrete examples of such a display apparatus, there are a liquid crystal display (LCD) apparatus, a quantum dot (QD) display apparatus, a field emission display (FED) apparatus, an organic light emitting diode (OLED) display apparatus, etc.

An OLED display apparatus includes, as a constituent element thereof, a light emitting diode including a cathode and an anode facing each other under the condition that an organic emission layer is interposed therebetween. As holes and electrons respectively injected from the cathode and the anode into the organic emission layer are coupled to each other in the organic emission layer, light is emitted and, as such, an image is displayed.

Thus, the OLED display apparatus is a self-luminous display apparatus and, as such, is not only advantageous in terms of power consumption according to low-voltage driving, but also has excellent color rendering, fast response time, wide viewing angle, and high contrast ratio (CR). In this regard, the OLED display apparatus is being highlighted as a next generation display apparatus, and research thereon is being conducted.

Meanwhile, in recent years, demand for a flexible display apparatus using a flexible substrate, such as a plastic substrate, has increased. Such a flexible display apparatus has advantages of a large-screen display and easy portability because the flexible display apparatus is portable in a folded state and displays an image in an unfolded state.

Since such a plastic substrate has flexible characteristics, it is difficult to use the plastic substrate itself in a process of manufacturing a display apparatus. For this reason, the process is performed under the condition that the plastic substrate is attached to one surface of a carrier substrate, such as a glass substrate.

That is, a plastic substrate is formed on a carrier substrate, and a thin film transistor array layer, a light emitting element array layer, and an encapsulation layer are then sequentially formed on the plastic substrate. Subsequently, a temporary protective film is attached to the encapsulation layer. Thereafter, the carrier substrate is removed from the plastic substrate and the temporary protective film is removed from the encapsulation layer. Finally, a polarization plate and a cover glass are bonded to the encapsulation layer.

In the manufacturing process as mentioned above, a phenomenon in which an end of a cathode is lifted may occur due to a force applied upon removal of the temporary protective film. As such, a failure may occur.

### SUMMARY

Accordingly, the present disclosure is directed to a display apparatus and a method of manufacturing the same that substantially obviate one or more problems due to limitations and disadvantages of the related art.

It is an object of the present disclosure to provide a display apparatus and a method of manufacturing the same which are capable of preventing or suppressing a cathode lifting phenomenon from occurring upon removal of a temporary protective film, thereby preventing or reducing occurrences of failures and achieving an enhancement in yield.

Objects of the present disclosure are not limited to the above-described objects, and other objects of the present disclosure will be more clearly understood by those skilled in the art from the following detailed description.

In accordance with an aspect of the present disclosure, a display apparatus may include a substrate including an active area configured to display an image and a non-active area disposed around the active area, a thin film transistor disposed on the substrate in the active area, a planarization layer disposed in the active area on the thin film transistor and in the non-active area, the planarization layer having a first contact hole over the thin film transistor, a bank layer disposed in the active area and the non-active area on the planarization layer, the bank layer having an open region in an emission area, a light emitting element disposed on the planarization layer to be connected to the thin film transistor through the first contact hole, and an organic insulating layer pattern disposed on the bank layer in the non-active area to cover an end of a cathode of the light emitting element.

In accordance with another aspect of the present disclosure, a method of manufacturing a display apparatus may include preparing a substrate including an active area configured to display an image and a non-active area disposed around the active area, forming a thin film transistor on the substrate in the active area, forming a voltage supply line on the substrate in the non-active area, forming a planarization layer on the thin film transistor and the voltage supply line such that the planarization layer has first and second contact holes over the thin film transistor and the voltage supply line, respectively, forming an anode of a light emitting element on the planarization layer such that the anode is connected to the thin film transistor through the first contact hole, forming a connection electrode on the planarization layer such that the connection electrode is connected to the voltage supply line through the second contact hole, forming a bank layer on the planarization layer with the anode and the connection electrode such that the bank layer is provided with an open region over the anode and with a third contact hole over the connection electrode, forming an emission layer on the anode in the open region, forming a cathode on the emission layer and the bank layer such that the cathode is electrically connected to the connection electrode through the third contact hole, and forming an organic insulating layer pattern on the bank layer in the non-active area such that the organic insulating layer pattern covers an end of the cathode, the third contact hole, and an end of the bank layer.

Detailed matters of other example embodiments are included in the following detailed description and the accompanying drawings.

In accordance with example embodiments of the present disclosure, a metal pattern is formed in a region overlapping with the end of the cathode of the light emitting element on the bank layer in the non-active area, and the end of the cathode overlapping with the metal pattern is then removed through laser irradiation. Accordingly, it may be possible to prevent or suppress an occurrence of a phenomenon in which, when a temporary protective film is removed for execution of a subsequent process, an underlayer is lifted due to a removal force applied thereto.

In accordance with example embodiments of the present disclosure, the organic insulating layer pattern is formed on the bank layer to cover the metal pattern, the end of the cathode, and the end of the bank layer. Accordingly, it may be possible to prevent or suppress an occurrence of the phenomenon in which, when the temporary protective film is removed for execution of a subsequent process, the cathode is lifted due to a removal force applied thereto. In addition, occurrences of failures in the manufacture of the display apparatuses may be reduced.

In addition, the organic insulating layer pattern may function as a dam blocking flow of an organic encapsulation layer during formation of an encapsulation layer. Accordingly, it may be unnecessary to form a separate dam and, as such, the process may be simplified, and a cell bezel may be reduced. In accordance with a reduction in cell bezel, a narrower bezel may be realized.

Since failures in the manufacturing of the display apparatuses are reduced, product costs may be reduced. In addition, environmental/social/governance (ESG) goals enabling a reduction in product costs may be achieved.

Effects according to the example embodiments of the present disclosure are not limited to the above-illustrated content, and various additional effects may be included in or learned from the practice of the present disclosure.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and along with the description serve to explain the principle of the disclosure. In the drawings:

FIG. 1 is a schematic sectional view of a flexible display apparatus according to an example embodiment of the present disclosure;

FIG. 2 is a circuit diagram of a sub-pixel included in the display apparatus according to an example embodiment of the present disclosure;

FIG. 3 is a view illustrating a cross-section of one pixel disposed in the active area of the display panel according to an example embodiment of the present disclosure;

FIG. 4 is a view illustrating a cross-section of a non-active area of the light emitting display panel according to an example embodiment of the present disclosure;

FIGS. 5A to 5E are views illustrating cross-sections of a display panel in an active area formed in processes according to an example embodiment of the present disclosure;

FIGS. 6A to 6E are views illustrating cross-sections of the display panel in a non-active area formed in the processes according to an example embodiment of the present disclosure; and

FIG. 7 is a plan view of the display panel in the bezel area according to an example embodiment of the present disclosure.

### DETAILED DESCRIPTION

Hereinafter, example embodiments of the present disclosure will be described in detail with reference to the accompanying drawings. Throughout the present disclosure, the same reference numerals designate the same constituent elements, respectively.

In the following description of the present disclosure, a detailed description of known technologies or configurations incorporated herein may be omitted where it may obscure the subject matter of the present disclosure. Furthermore, the following terms associated with constituent elements are selected taking into consideration ease of preparation of the disclosure, and may differ from the names of the corresponding elements in practice.

The shape, size, ratio, angle, number and the like shown in the drawings to illustrate the example embodiments of the present disclosure are only for illustration and are not limited to the contents shown in the drawings. Wherever possible, the same reference numbers will be used throughout the drawings to refer to the same or like parts.

In the following description, detailed descriptions of known technologies related to the present disclosure may be omitted so as not to unnecessarily obscure the subject matter of the present disclosure.

Where terms such as “including”, “having”, and “comprising” are used throughout the specification, an additional component may be present, unless a more limiting term like “only” is used. A component described in a singular form encompasses components in a plural form, and vice versa, unless particularly stated otherwise.

It should be interpreted that the components included in the example embodiments of the present disclosure include an error range, although there is no additional particular description thereof.

In describing a variety of embodiments of the present disclosure, where terms for a positional relationship such as “on”, “above”, “under” and “next to” are used, at least one intervening element may be present between two elements unless a more limiting term like “immediately” or “directly” is used.

In describing a variety of embodiments of the present disclosure, where a temporal relationship is described, for example, where terms for temporal relationship of events such as “after”, “subsequently”, “next”, and “before” are used, there may also be the case in which the events are not continuous, unless a more limiting term like “immediately” or “directly” is used.

In the meantime, although terms including an ordinal number, such as first or second, may be used to describe a variety of constituent elements, the constituent elements are not limited to the terms, and the terms are used only for the purpose of discriminating one constituent element from other constituent elements. Accordingly, a first constituent element may represent a second constituent element, and vice versa, within the scope of the present disclosure unless particularly stated otherwise.

The respective features of various example embodiments according to the present disclosure can be partially or entirely joined or combined and technically variably related or operated, and the embodiments can be implemented independently or in combination.

Hereinafter, a display apparatus according to example embodiments of the present disclosure will be described with reference to the accompanying drawings.

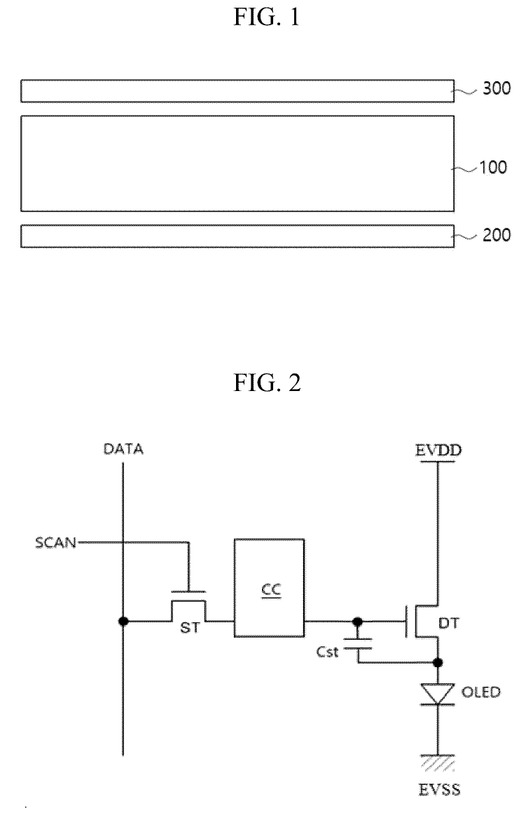

FIG. 1 is a schematic sectional view of a flexible display apparatus according to an example embodiment of the present disclosure. FIG. 2 is a circuit diagram of a sub-pixel included in the display apparatus according to the example embodiment of the present disclosure.

As shown in FIG. 1, the display apparatus according to the example embodiment of the present disclosure may include a display panel 100, a back plate 200 disposed under the display panel 100, and a cover window 300 disposed over the display panel 100.

The cover window 300 may be constituted by a reinforced glass or a plastic film having impact resistance and light transparency to protect the display panel 100 from external impact, moisture, heat, etc. When the cover window 300 is constituted by the plastic film, the plastic film may include a polyimide (PI) film, a polyethylene terephthalate (PET) film, a polypropylene glycol (PPG) film, a polycarbonate (PC) film, or the like, without being limited thereto.

When the cover window 300 is made of the reinforced glass, the cover window 300 may be broken by external force or stress. To prevent or suppress fragments of the cover window 300 from scattering in this case, an anti-scattering film may be attached to an upper surface of the cover window 300. The anti-scattering film may include, for example, a base film including polyethylene terephthalate (PET), colorless polyimide (CPI), a laminate of polyethylene terephthalate (PET) and colorless polyimide (CPI), or the like. A hard coating layer, an anti-reflection layer, an anti-fingerprint layer, etc. may be coated on an upper surface of the base film.

The display panel 100 may include an active area in which a plurality of pixels is disposed to display an image, and a non-active area disposed around the active area to surround the active area.

The display panel 100 may be a flexible display panel including a plurality of sub-pixels formed on a flexible substrate. The display panel 100 may be an organic light emitting diode panel.

When the display panel 100 is the organic light emitting diode panel, each sub-pixel includes a light emitting element, and a pixel circuit configured to control driving of the light emitting element. In this case, the light emitting element may be constituted by an anode, a cathode, and an emission layer between the anode and the cathode.

As shown in FIG. 2, each sub-pixel may include a switching transistor ST, a driving transistor DT, a compensation circuit CC, a light emitting element OLED, and a storage capacitor Cst.

The light emitting element OLED may operate to emit light in accordance with drive current formed by the driving transistor DT.

The switching transistor ST may perform a switching operation such that a data signal supplied through a data line, correspondingly to a scan signal supplied through a gate line, is stored in the storage capacitor Cst as a data voltage. The storage capacitor Cst may maintain the data voltage for one frame.

The driving transistor DT may operate to enable constant drive current to flow between a high-level drive voltage supply line EVDD and a low-level drive voltage supply line EVSS, correspondingly to the data voltage stored in the storage capacitor Cst.

The compensation circuit CC is a circuit configured to compensate a threshold voltage, etc. of the driving transistor DT. The compensation circuit CC may include one or more thin film transistors and one or more capacitors. The compensation circuit CC may have various configurations in accordance with a compensation method thereof.

For example, although the sub-pixel shown in FIG. 2 is configured to have a 2T(transistor)1C(capacitor) structure including the switching transistor ST, the driving transistor DT, the storage capacitor Cst, and the light emitting element OLED, the sub-pixel may be configured to have various structures of 3T1C, 4T2C, 5T2C, 6T1C, 6T2C, 7T1C, 7T2C, 8T1C, etc. when the compensation circuit CC is added thereto.

Each sub-pixel may be divided into a red pixel, a green pixel, and a blue pixel, for color rendering. The sub-pixel may further include a white pixel.

The back plate 200 may be constituted by a polymer film. The polymer film usable for the back plate 200 may be made of polyimide (PI), polyethylene terephthalate (PET), polycarbonate (PC), or polyethylene naphthalate (PEN), without being limited thereto.

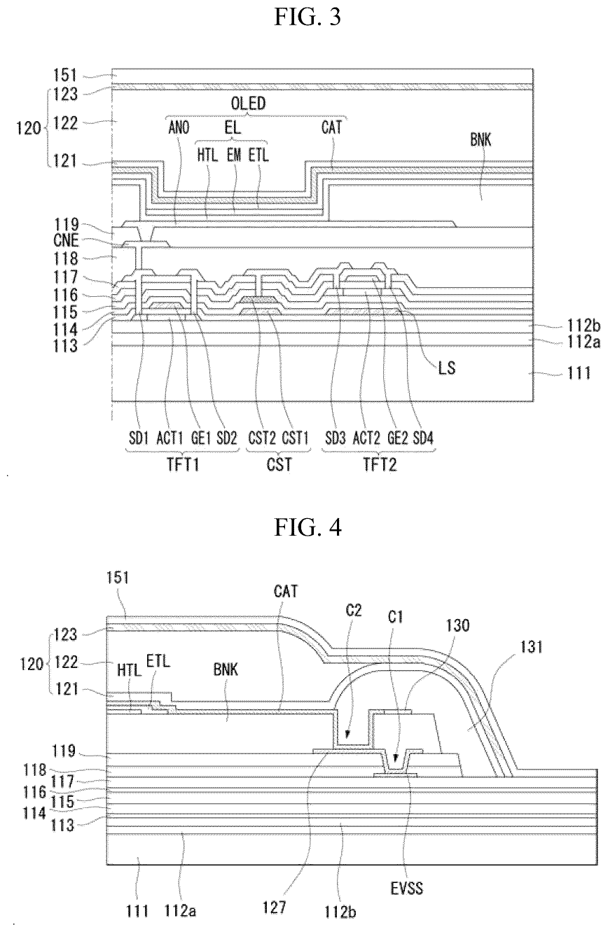

FIG. 3 is a view illustrating a cross-section of one pixel disposed in the active area of the display panel according to an example embodiment of the present disclosure.

A light emitting element OLED, transistors TFT1 and TFT2 and a capacitor CST, which are configured to drive the light emitting element OLED, and an encapsulation layer 120 may be disposed on a substrate 111 of the active area.

The transistors TFT1 and TFT2 may include a silicon thin film transistor including a polycrystalline semiconductor material and an oxide thin film transistor including an oxide semiconductor material. In this case, the thin film transistor including the polycrystalline semiconductor material may be referred to as a “polycrystalline thin film transistor TFT1”, and the thin film transistor including the oxide semiconductor material may be referred to as an “oxide thin film transistor TFT2”. For example, the polycrystalline thin film transistor TFT1 may be a transistor connected to the light emitting element OLED, and the oxide thin film transistor TFT2 may be a transistor connected to the capacitor CST.

On the contrary, the thin film transistor including the polycrystalline semiconductor material may be referred to as a “polycrystalline thin film transistor TFT2”, and the thin film transistor including the oxide semiconductor material may be referred to as an “oxide thin film transistor TFT1”. For example, the polycrystalline thin film transistor TFT2 may be a transistor connected to the capacitor CST, and the oxide thin film transistor TFT2 may be a transistor connected to the light emitting element OLED.

In the following description, the thin film transistor including the polycrystalline semiconductor material may be referred to as a “polycrystalline thin film transistor TFT1”, and the thin film transistor including the oxide semiconductor material may be referred to as an “oxide thin film transistor TFT2”.

The substrate 111 may be a flexible substrate. When the substrate 111 is a flexible substrate, the substrate 111 may be implemented to have a multilayer structure in which an organic layer and an inorganic layer are alternately stacked. For example, the substrate 111 may be configured to have a structure in which an organic layer made of, for example, polyimide, and an inorganic layer made of, for example, silicon oxide (SiO₂), are alternately stacked.

A lower buffer layer 112a may be formed on the substrate 111. The lower buffer layer 112a may be configured to block introduction of moisture, etc. from the outside. The lower buffer layer 112a may be constituted by a silicon oxide (SiO₂) layer or the like stacked to form a multilayer structure. An auxiliary buffer layer 112b may be further disposed on the lower buffer layer 112a to protect the elements from moisture.

The polycrystalline thin film TFT1 may be formed on the substrate 111. The polycrystalline thin film transistor TFT1 may use a polycrystalline semiconductor as an active layer thereof. The polycrystalline thin film transistor TFT1 may include a first active layer ACT1 including a channel, through which electrons or holes move, a first gate electrode GE1, a first source electrode SD1, and a first drain electrode SD2. A first gate insulating layer 113 may be disposed between the first gate electrode GE1 and the first active layer ACT1. The first gate insulating layer 113 may be constituted by an inorganic layer, such as a silicon oxide layer (SiO₂) layer, a silicon nitride (SiNₓ) layer, or the like, stacked to have a single-layer structure or a multilayer structure.

The first active layer ACT1 may include a first channel region, a first source region disposed at one side of the first channel region, and a first drain region disposed at the other side of the first channel region. In this case, the first channel region is disposed between the first source region and the first drain region. The first source region and the first drain region are regions treated to have conductivity through doping of an intrinsic polycrystalline semiconductor material with group-V or III impurity ions such as phosphorous (P) or boron (B) ions in a predetermined concentration. In the first channel region, the polycrystalline semiconductor material is maintained in an intrinsic state and, as such, the first channel region may provide a path for movement of electrons and holes.

In accordance with an embodiment, the polycrystalline thin film transistor TFT1 may be implemented to have a top-gate structure in which the first gate electrode GE1 is disposed over the first active layer ACT1. Accordingly, a first electrode CST1 included in the capacitor CST and a light shielding layer LS included in the oxide thin film transistor TFT2 may be formed using the same material as that of the first gate electrode GE1. In this case, the first gate electrode GE1, the first electrode CST1, and the light shielding layer LS may be formed through a single mask process and, as such, the number of mask processes may be reduced.

The first gate electrode GE1 may be made of a metal material. For example, the first gate electrode GE1 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof, without being limited thereto.

A first interlayer insulating layer 114 may be disposed on the first gate electrode GE1. The first interlayer insulating layer 114 may be implemented using silicon oxide (SiO₂), silicon nitride (SiNₓ), or the like.

The display panel 100 may further include an upper buffer layer 115, a second gate insulating layer 116, and a second interlayer insulating layer 117 sequentially disposed over the first interlayer insulating layer 114.

The first source electrode SD1 and the first drain electrode SD2 of the polycrystalline thin film transistor TFT1 may be formed on the second interlayer insulating layer 117. The first source electrode SD1 and the first drain electrode SD2 of the polycrystalline thin film transistor TFT1 may be respectively connected to the first source region and the first drain region of the first active layer ACT1 through contact holes extending through the first gate insulating layer 113, the first interlayer insulating layer 114, the upper buffer layer 115, the second gate insulating layer 116, and the second interlayer insulating layer 117.

The upper buffer layer 115 may space a second active layer ACT2 of the oxide thin film transistor TFT2 implemented using an oxide semiconductor material from the first active layer ACT1 implemented using a polycrystalline semiconductor material, and may provide a base for formation of the second active layer ACT2.

The oxide thin film transistor TFT2 may be formed on the upper buffer layer 115. The oxide thin film transistor TFT2 may include the second active layer ACT2 implemented using an oxide semiconductor material, a second gate electrode GE2 disposed on the second gate insulating layer 116, and a second source electrode SD3 and a second drain electrode SD4 disposed on the second interlayer insulating layer 117.

The second active layer ACT2 may be implemented using an oxide semiconductor material and may include a second channel region configured to be intrinsic without being doped with impurities, and a second source region and a second drain region treated to have conductivity through doping with impurities.

The oxide thin film transistor TFT2 may further include the light shielding layer LS which is disposed under the upper buffer layer 115 to overlap with the second active layer ACT2. The light shielding layer LS blocks light incident from the side of the substrate 111, thereby securing reliability of the oxide thin film transistor TFT2. The light shielding layer LS may be made of the same material as that of the first gate electrode GE1 and may be formed at an upper surface of the first gate insulating layer 113. The light shielding layer LS may be electrically connected to the second gate electrode GE2, thereby constituting a dual gate.

The second source electrode SD3 and the second drain electrode SD4 may be formed on the second interlayer insulating layer 117 simultaneously with the first source electrode SD1 and the first drain electrode SD2, using the same material as that of the first source electrode SD1 and the first drain electrode SD2. Accordingly, the number of mask processes may be reduced.

The second gate insulating layer 116 may cover the second active layer ACT2 of the oxide thin film transistor TFT2. The second gate insulating layer 116 may be implemented using an inorganic layer because the second gate insulating layer 116 is formed over the second active layer ACT2 implemented using an oxide semiconductor material. For example, the second gate insulating layer 116 may be made of silicon oxide (SiO₂), silicon nitride (SiNₓ), or the like.

The second gate electrode GE2 may be made of a metal material. For example, the second gate electrode GE2 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof, without being limited thereto.

Meanwhile, the first electrode CST1 may be disposed on the first gate insulating layer 113, and a second electrode CST2 may be disposed on the first interlayer insulating layer 114 such that the second electrode CST2 overlaps with the first electrode CST1, thereby implementing the capacitor CST. The first electrode CST1 may be formed using the same material as that of the light shielding layer LS and the first gate electrode GE1.

For example, the second electrode CST2 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof.

The capacitor CST may function to store a data voltage applied thereto through a data line DL, for a predetermined period. The capacitor CST may include two electrodes facing each other, and a dielectric disposed between the two electrodes. The first interlayer insulating layer 114 may be disposed between the first electrode CST1 and the second electrode CST2.

The first electrode CST1 or the second electrode CST2 of the capacitor CST may be electrically connected to the second source electrode SD3 or the second drain electrode SD4 of the oxide thin film transistor TFT2. Of course, the connection relation of the capacitor CST may be varied in accordance with the sub-pixel driving circuit, without being limited to the above-described connection relation.

A first planarization layer 118 and a second planarization layer 119 may be sequentially disposed over the polycrystalline thin film transistor TFT1, the oxide thin film transistor TFT2 and the capacitor CST, for surface planarization. Each of the first planarization layer 118 and the second planarization layer 119 may be an organic layer made of polyimide or acryl resin. The light emitting element OLED may be formed on the second planarization layer 119.

The light emitting element OLED may include an anode ANO, a cathode CAT, and an emission layer EL disposed between the anode ANO and the cathode CAT. When the sub-pixel driving circuit is implemented to use a low-level drive voltage connected to the cathode CAT in common, the anode ANO is disposed as a separate electrode for each sub-pixel. On the other hand, when the sub-pixel driving circuit is implemented to use a high-level drive voltage in common, the cathode CAT may be disposed as a separate electrode for each sub-pixel.

The light emitting element OLED may be electrically connected to a driving element through an intermediate electrode CNE disposed on the first planarization layer 118. For example, the anode ANO of the light emitting element OLED and the first source electrode SD1 of the polycrystalline thin film transistor TFT1 may be interconnected by the intermediate electrode CNE.

The anode ANO may be connected to the intermediate electrode CNE which is exposed through a contact hole extending through the second planarization layer 119. The intermediate electrode CNE may be connected to the first source electrode SD1 which is exposed through a contact hole extending through the first planarization layer 118.

The intermediate electrode CNE functions as a medium for interconnecting the first source electrode SD1 and the anode ANO. The intermediate electrode CNE may be made of a conductive material such as copper (Cu), silver (Ag), molybdenum (Mo), or titanium (Ti).

The second planarization layer 119 and the intermediate electrode CNE may be omitted. When the second planarization layer 119 and the intermediate electrode CNE are omitted, the anode ANO may be directly electrically connected to the first source electrode SD1 exposed through the contact hole extending through the first planarization layer 118.

The anode ANO may be formed to have a multilayer structure including a transparent conductive layer and an opaque conductive layer having high reflection efficiency. The transparent conductive layer may be made of a material having a relatively great work function, for example, indium tin oxide (ITO) or indium zinc oxide (IZO). The opaque conductive layer may be formed to have a single-layer structure or a multilayer structure including aluminum (Al), silver (Ag), copper (Cu), lead (Pb), molybdenum (Mo), titanium (Ti) or an alloy thereof. For example, the anode ANO may be formed to have a structure in which a transparent conductive layer, an opaque conductive layer and a transparent conductive layer are sequentially stacked or a structure in which a transparent conductive layer and an opaque conductive layer are sequentially stacked.

A bank layer BNK may be a sub-pixel definition layer configured to expose the anode ANO of each sub-pixel. The bank layer BNK may be formed of an opaque material (for example, a black) to prevent or suppress light interference between adjacent sub-pixels. In this case, the bank layer BNK may include a light shielding material made of at least one of a color pigment, an organic black pigment, or a carbon black pigment.

The emission layer EL may be formed through stacking of a hole-associated layer including a hole injection layer HIL and a hole transport layer HTL, an organic emission layer including an emission layer EM, and an electron-associated layer including an electron transport layer ETL and an electron injection layer EIL in this order or in reverse order. Although only the hole transport layer HTL, the emission layer EM and the electron transport layer ETL are shown in FIG. 3, the present disclosure is not limited thereto.

The cathode CAT is formed on an upper surface and a side surface of the emission layer EL to face the anode ANO under the condition that the emission layer EL is interposed between the cathode CAT and the anode ANO. The cathode CAT may be formed to have an integrated structure covering the entirety of the active area. When the cathode CAT is applied to a top-emission type organic light emitting display apparatus, the cathode CAT may be constituted by a transparent conductive layer made of, for example, indium tin oxide (ITO) or indium zinc oxide (IZO).

In addition, an encapsulation layer 120 configured to suppress moisture penetration may be further disposed on the cathode CAT. The encapsulation layer 120 may prevent or block penetration of ambient moisture or oxygen into the light emitting layer EL which is vulnerable to ambient moisture or oxygen. For this function, the encapsulation layer 120 may include at least one inorganic encapsulation layer and at least one organic encapsulation layer, without being limited thereto. The encapsulation layer 120 may include a first encapsulation layer 121, a second encapsulation layer 122, and a third encapsulation layer 123 sequentially stacked.

The first encapsulation layer 121 and the third encapsulation layer 123 may be made of an inorganic insulating material depositable at a low temperature, such as silicon nitride (SiNₓ), silicon oxide (SiOₓ), silicon oxynitride (SiON), or aluminum oxide (Al₂O₃). Since the first encapsulation layer 121 and the third encapsulation layer 123 are deposited in a low-temperature atmosphere, it may be possible to prevent or protect the emission layer EL, which is vulnerable to a high-temperature atmosphere, from being damaged during a deposition process for the first encapsulation layer 121 and the third encapsulation layer 123.

The second encapsulation layer 122 may perform a buffering function for alleviating stress generated between adjacent layers due to bending of the display apparatus, and may planarize steps of adjacent layers. The second encapsulation layer 122 may be made of a non-photosensitive organic insulating material such as acryl resin, epoxy resin, phenolic resin, polyamide resin, polyimide resin, polyethylene or silicon oxycarbide (SiOC), or a photosensitive organic insulating material such as photoreactive acrylic, without being limited thereto.

A temporary protective film 151 may be disposed on the encapsulation layer 120, for execution of a subsequent process. The temporary protective film 151 may be removed (peeled off) before execution of the subsequent process.

FIG. 4 is a view illustrating a cross-section of a non-active area of the light emitting display panel according to an example embodiment of the present disclosure.

The layers and configurations thereof shown in FIG. 4 are identical to those described with reference to FIG. 3. Thus, the same reference numerals as those of FIG. 3 are designated thereto, and concrete materials thereof may be omitted.

The lower buffer layer 112a and the auxiliary buffer layer 112b may be disposed on the substrate 111 in the non-active area to block introduction of moisture, etc. from the outside.

In addition, the first gate insulating layer 113, the first interlayer insulating layer 114, the upper buffer layer 115, the second gate insulating layer 116, and the second interlayer insulating layer 117 are disposed on the substrate 111 in the non-active area.

A low-level drive voltage supply line EVSS configured to supply the low-level drive voltage EVSS may be disposed on the second interlayer insulating layer 117.

The first planarization layer 118 and the second planarization layer 119 may be sequentially disposed on the low-level drive voltage supply line EVSS, for surface planarization. As described with reference to FIG. 3, the second planarization layer 119 may be omitted. The first planarization layer 118 and the second planarization layer 119 on the low-level drive voltage supply line EVSS may be selectively removed to expose the low-level drive voltage supply line EVSS and, as such, a first contact hole C1 may be formed.

A connection electrode 127 may be disposed on the second planarization layer 119. The connection electrode 127 may be formed using the same material as that of the anode ANO of the light emitting element OLED described with reference to FIG. 3. The connection electrode 127 may be electrically connected to the low-level drive voltage supply line EVSS through the first contact hole C1.

The bank layer BNK may be disposed on the connection electrode 127. The bank layer BNK has a second contact hole C2 to expose the connection electrode 127. The hole transport layer HTL and the electron transport layer ETL, which are a part of the emission layer EL, may extend to be disposed on the bank layer BNK in the non-active layer.

The cathode CAT of the light emitting element OLED may extend to be disposed on the bank layer BNK in the non-active area. The cathode CAT may be electrically connected to the connection electrode 127 through the second contact hole C2.

A metal pattern 130 may be formed on the bank layer BNK at an end of the cathode CAT in the non-active area.

An organic insulating layer pattern 131 may be formed on the bank layer BNK to cover the metal pattern 130, the end of the cathode CAT, the second contact hole C2, and an end of the bank layer BNK. The organic insulating layer pattern 131 may include a high-viscosity material. For example, the organic insulating layer pattern 131 may be formed of a non-photosensitive organic insulating material such as acryl resin, epoxy resin, phenolic resin, polyamide resin, polyimide resin, polyethylene or silicon oxycarbide (SiOC), or a photosensitive organic insulating material such as photoreactive acrylic.

The encapsulation layer 120 configured to suppress penetration of moisture may be disposed on the cathode CAT and the organic insulating layer pattern 131. The encapsulation layer 120 may include the first encapsulation layer 121, the second encapsulation layer 122, and the third encapsulation layer 123 sequentially stacked.

The first encapsulation layer 121 may extend from the active area to the non-active area such that the first encapsulation layer 121 is disposed in both the active area and the non-active area. The first encapsulation layer 121 may extend to a bezel area via the organic insulating layer pattern 131.

The second encapsulation layer 122 may extend from the active area to the non-active area such that the second encapsulation layer 122 is disposed on the first encapsulation layer 121. The second encapsulation layer 122 may extend to an inside of the organic insulating layer pattern 131.

The third encapsulation layer 123 may extend from the active area to the non-active area such that the third encapsulation layer 123 is disposed on the second encapsulation layer 122 and the first encapsulation layer 121. The third encapsulation layer 123 may extend to the bezel area via the organic insulating layer pattern 131.

The temporary protective film 151 may be disposed on the encapsulation layer 120 to extend over the active area and the non-active area, for execution of a subsequent process. The temporary protective film 151 may be removed (peeled off) before execution of the subsequent process.

Hereinafter, a method of manufacturing a display apparatus in accordance with an example embodiment of the present disclosure will be described.

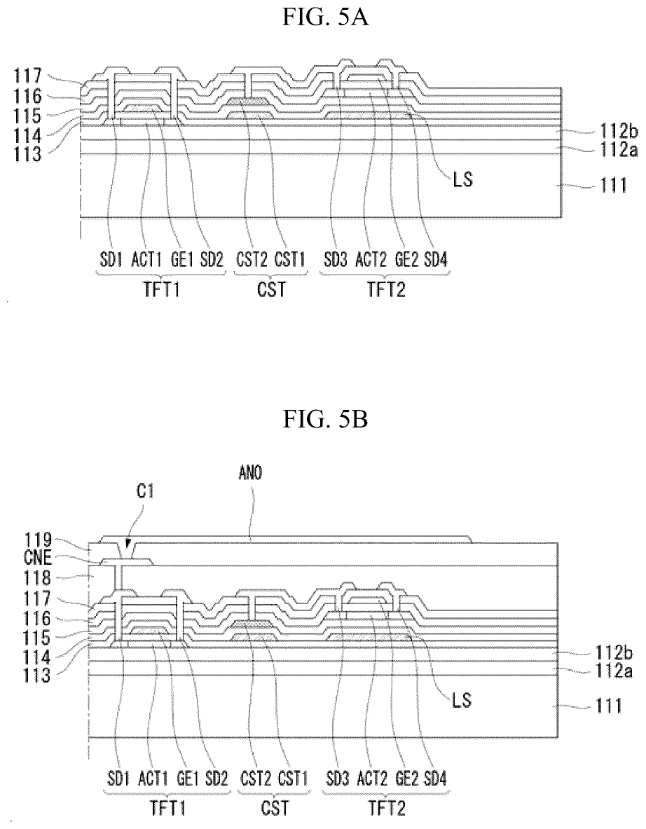

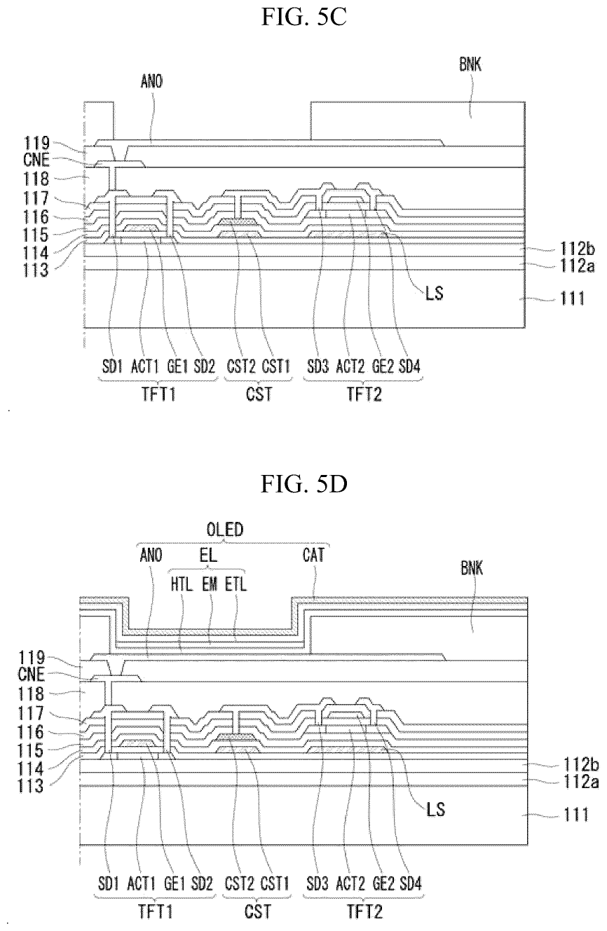

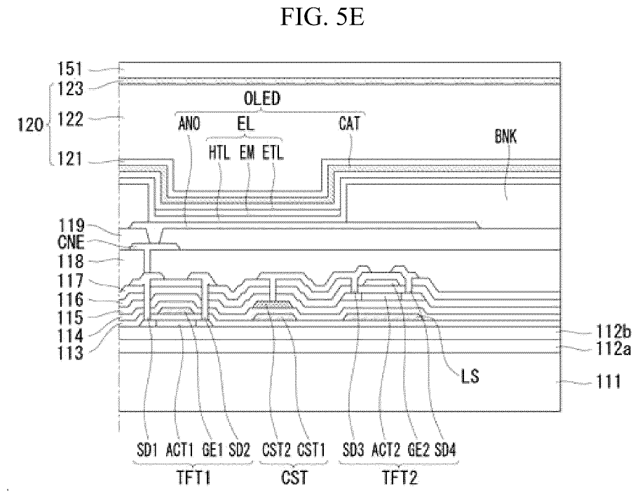

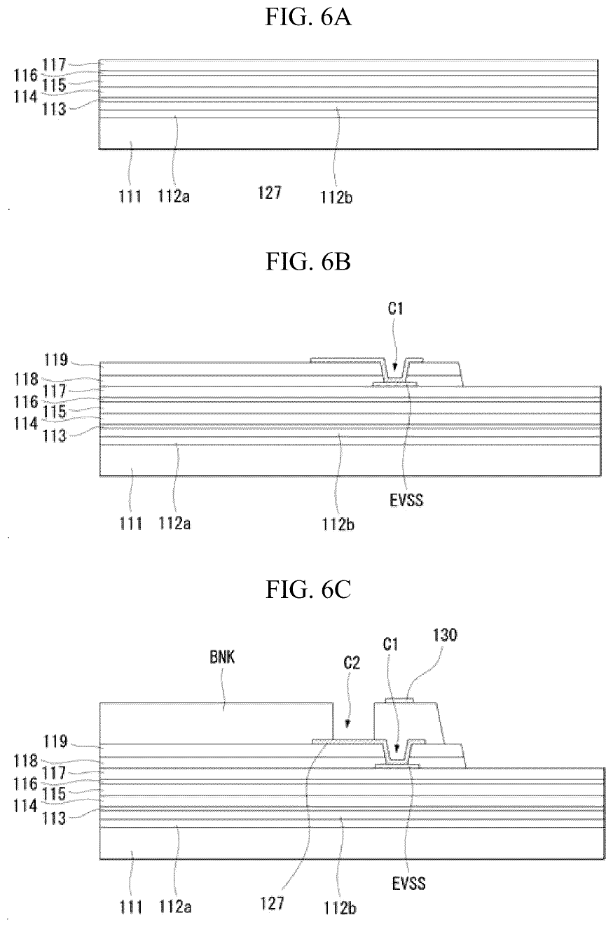

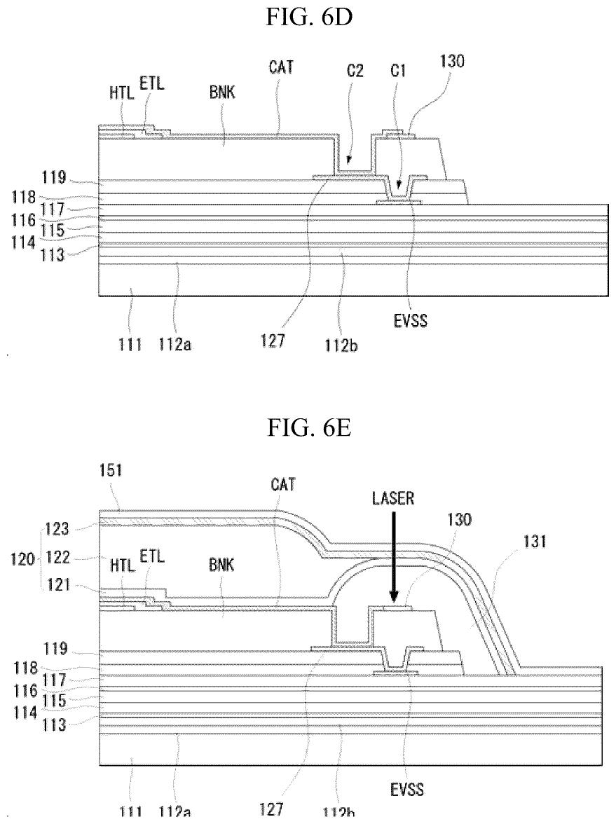

FIGS. 5A to 5E are views illustrating cross-sections of a display panel in an active area formed in processes according to an example embodiment of the present disclosure. FIGS. 6A to 6E are views illustrating cross-sections of the display panel in a non-active area formed in the processes according to the example embodiment of the present disclosure.

As shown in FIGS. 5A and 6A, a substrate 111 is prepared. The substrate 111 may be a flexible substrate. When the substrate 111 is a flexible substrate, the substrate 111 may be implemented to have a multilayer structure in which an organic layer and an inorganic layer are alternately stacked. For example, the substrate 111 may be configured to have a structure in which an organic layer made of, for example, polyimide, and an inorganic layer made of, for example, silicon oxide (SiO₂), are alternately stacked.

Since such a plastic substrate has flexible characteristics, it is difficult to use the plastic substrate itself in a process of manufacturing a display apparatus. For this reason, the process is performed under the condition that the plastic substrate is attached to one surface of a carrier substrate such as a glass substrate.

That is, a plastic substrate is formed on a carrier substrate, and a thin film transistor array layer, a light emitting element array layer and an encapsulation layer, which will be described later, are then sequentially formed on the plastic substrate. Subsequently, a temporary protective film is attached to the encapsulation layer. Thereafter, the carrier substrate is removed from the plastic substrate and the temporary protective film is removed from the encapsulation layer. Finally, a polarization plate and a cover glass are bonded to the encapsulation layer. In FIGS. 5A and 6A, a state in which the carrier substrate is omitted is shown.

A lower buffer layer 112a and an auxiliary buffer layer 112b may be sequentially formed on the substrate 111 in both the active area and the non-active area. The lower buffer layer 112a may be configured to block introduction of moisture, etc. from the outside. The lower buffer layer 112a may be constituted by a silicon oxide (SiO₂) layer or the like stacked to form a multilayer structure. At least one of the lower buffer layer 112a or the auxiliary buffer layer 112b may be omitted.

A first thin film transistor TFT1, a capacitor CST, and a second thin film transistor TFT2 may be formed on the substrate 111 in the active area. The first thin film transistor TFT1 may use a polycrystalline semiconductor as an active layer thereof. The first thin film transistor TFT1, which is a polycrystalline thin film transistor, may include a first active layer ACT1 including a channel, through which electrons or holes move, a first gate electrode GE1, a first source electrode SD1, and a first drain electrode SD2. A first gate insulating layer 113 may be disposed between the first gate electrode GE1 and the first active layer ACT1. The first gate insulating layer 113 may be constituted by an inorganic layer, such as a silicon oxide layer (SiO₂) layer, a silicon nitride (SiNₓ) layer, or the like, stacked to have a single-layer structure or a multilayer structure.

The first active layer ACT1 may include a first channel region, a first source region disposed at one side of the first channel region, and a first drain region disposed at the other side of the first channel region. The first channel region is disposed between the first source region and the first drain region. The first source region and the first drain region are regions treated to have conductivity through doping of an intrinsic polycrystalline semiconductor material with group-V or III impurity ions such as phosphorous (P) or boron (B) in a predetermined concentration. In the first channel region, the polycrystalline semiconductor material is maintained in an intrinsic state and, as such, the first channel region may provide a path for movement of electrons and holes.

In accordance with an embodiment, the first thin film transistor TFT1 may be implemented to have a top-gate structure in which the first gate electrode GE1 is disposed over the first active layer ACT1. Accordingly, a first electrode CST1 included in the capacitor CST and a light shielding layer LS included in the second thin film transistor TFT2, which is an oxide thin film transistor, may be formed using the same material as that of the first gate electrode GE1. In this case, the first gate electrode GE1, the first electrode CST1, and the light shielding layer LS may be formed through a single mask process and, as such, the number of mask processes may be reduced.

The first gate electrode GE1 may be made of a metal material. For example, the first gate electrode GE1 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof, without being limited thereto.

A first interlayer insulating layer 114 may be disposed on the first gate electrode GE1. The first interlayer insulating layer 114 may be implemented using silicon oxide (SiO₂), silicon nitride (SiNₓ), or the like.

The substrate 111 may further include an upper buffer layer 115, a second gate insulating layer 116, and a second interlayer insulating layer 117 sequentially disposed over the first interlayer insulating layer 114.

The first source electrode SD1 and the first drain electrode SD2 of the first thin film transistor TFT1 may be formed on the second interlayer insulating layer 117. The first source electrode SD1 and the first drain electrode SD2 of the first thin film transistor TFT1 may be respectively connected to the first source region and the first drain region of the first active layer ACT1 through contact holes extending through the first gate insulating layer 113, the first interlayer insulating layer 114, the upper buffer layer 115, the second gate insulating layer 116, and the second interlayer insulating layer 117.

The upper buffer layer 115 may space a second active layer ACT2 of the second thin film transistor TFT2 implemented using an oxide semiconductor material from the first active layer ACT1 implemented using a polycrystalline semiconductor material, and may provide a base for formation of the second active layer ACT2.

The second thin film transistor TFT2 may be formed on the upper buffer layer 115. The second thin film transistor TFT2 may include the second active layer ACT2 implemented using an oxide semiconductor material, a second gate electrode GE2 disposed on the second gate insulating layer 116, and a second source electrode SD3 and a second drain electrode SD4 disposed on the second interlayer insulating layer 117.

The second active layer ACT2 may be implemented using an oxide semiconductor material and may include a second channel region configured to be intrinsic without being doped with impurities, and a second source region and a second drain region treated to have conductivity through doping with impurities.

The second thin film transistor TFT2 may further include the light shielding layer LS which is disposed under the upper buffer layer 115 to overlap with the second active layer ACT2. The light shielding layer LS blocks light incident from the side of the substrate 111, thereby securing reliability of the second thin film transistor TFT2. The light shielding layer LS may be made of the same material as that of the first gate electrode GE1 and may be formed at an upper surface of the first gate insulating layer 113. The light shielding layer LS may be electrically connected to the second gate electrode GE2, thereby constituting a dual gate.

The second source electrode SD3 and the second drain electrode SD4 may be formed on the second interlayer insulating layer 117 simultaneously with the first source electrode SD1 and the first drain electrode SD2, using the same material as that of the first source electrode SD1 and the first drain electrode SD2. Accordingly, the number of mask processes may be reduced.

A low-level drive voltage supply line EVSS is formed on the second interlayer insulating layer 117 in the non-active area, using the same material as that of the first source electrode SD1, the first drain electrode SD2, the second source electrode SD3, and the second drain electrode SD4.

The second gate insulating layer 116 may cover the second active layer ACT2 of the second thin film transistor TFT2. The second gate insulating layer 116 may be implemented using an inorganic layer because the second gate insulating layer 116 is formed over the second active layer ACT2 implemented using an oxide semiconductor material. For example, the second gate insulating layer 116 may be made of silicon oxide (SiO₂), silicon nitride (SiNₓ), or the like.

The second gate electrode GE2 may be made of a metal material. For example, the second gate electrode GE2 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof, without being limited thereto.

Meanwhile, the first electrode CST1 may be disposed on the first gate insulating layer 113, and a second electrode CST2 may be disposed on the first interlayer insulating layer 114 such that the second electrode CST2 overlaps with the first electrode CST1, thereby implementing the capacitor CST. The first electrode CST1 may be formed using the same material as that of the light shielding layer LS and the first gate electrode GE1.

For example, the second electrode CST2 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof.

The capacitor CST may function to store a data voltage applied thereto through a data line DL, for a predetermined period. The capacitor CST may include two electrodes facing each other, and a dielectric disposed between the two electrodes. The first interlayer insulating layer 114 may be disposed between the first electrode CST1 and the second electrode CST2.

The first electrode CST1 or the second electrode CST2 of the capacitor CST may be electrically connected to the second source electrode SD3 or the second drain electrode SD4 of the second thin film transistor TFT2. Of course, the connection relation of the capacitor CST may be varied in accordance with a sub-pixel driving circuit, without being limited to the above-described connection relation.

The first gate insulating layer 113, the first interlayer insulating layer 114, the upper buffer layer 115, the second gate insulating layer 116, and the second interlayer insulating layer 117 may be formed to extend to the non-active area on the substrate 111, as shown in FIG. 6A.

As shown in FIGS. 5B and 6B, a first planarization layer 118 may be formed on the first thin film transistor TFT1, the second thin film transistor TFT2 and the capacitor CST, for surface planarization. The first planarization layer 118 is then selectively removed to expose the first source electrode SD1, thereby forming a contact hole.

A conductive material such as copper (Cu), silver (Ag), or titanium (Ti) is deposited on the first planarization layer 118, and is then selectively removed such that an intermediate electrode CNE is formed on the first planarization layer 118 in the active area to be electrically connected to the first source electrode SD1 through the contact hole.

A second planarization layer 119 is formed on the first planarization layer 118 including the intermediate electrode CNE. A first contact hole C1 is formed through the first and second planarization layers 118 and 119 to expose the intermediate electrode CNE and the low-level drive voltage supply line EVSS.

The first planarization layer 118 and the second planarization layer 110 may be organic layers made of polyimide or acryl resin.

An anode ANO is formed on the second planarization layer 119 in the active area such that the anode ANO is electrically connected to the intermediate electrode CNE through the first contact hole C1. At the same time, a connection electrode 127 is formed on the second planarization layer 119 in the non-active area such that the connection electrode 127 is electrically connected to the low-level drive voltage supply line EVSS through the first contact hole C1.

The anode ANO and the connection electrode 127 may be formed to have a multilayer structure including a transparent conductive layer and an opaque conductive layer having high reflection efficiency. The transparent conductive layer may be made of a material having a relatively great work function, for example, indium tin oxide (ITO) or indium zinc oxide (IZO). The opaque conductive layer may be formed to have a single-layer structure or a multilayer structure including aluminum (Al), silver (Ag), copper (Cu), lead (Pb), molybdenum (Mo), titanium (Ti) or an alloy thereof. For example, the anode ANO may be formed to have a structure in which a transparent conductive layer, an opaque conductive layer and a transparent conductive layer are sequentially stacked or a structure in which a transparent conductive layer and an opaque conductive layer are sequentially stacked.

The second planarization layer 119 and the intermediate electrode CNE may be omitted. When the second planarization layer 119 and the intermediate electrode CNE are omitted, the anode ANO, which will be subsequently formed, may be directly electrically connected to the first source electrode SD1 exposed through the contact hole extending through the first planarization layer 118.

As shown in FIGS. 5C and 6C, a bank layer BNK is formed on the second planarization layer 119 including the anode ANO and the connection electrode 127. Thereafter, the bank layer BNK is selectively removed to form an open region on the anode ANO and to form a second contact hole C2 at the connection electrode 127.

The bank layer BNK may be a sub-pixel definition layer configured to expose the anode ANO of each sub-pixel. The bank layer BNK may be formed of an opaque material (for example, a black) to prevent or suppress light interference between adjacent sub-pixels. In this case, the bank layer BNK may include a light shielding material made of at least one of a color pigment, an organic black pigment, or a carbon black pigment.

Subsequently, as shown in FIG. 6C, a metal pattern 130 may be formed on the bank layer BNK in the non-active area. The metal pattern 130 may be formed at a position overlapping with an end of a cathode CAT which will be subsequently formed.

As shown in FIGS. 5D and 6D, an emission layer EL is formed on the anode ANO. The emission layer EL may be formed through stacking of a hole-associated layer including a hole injection layer HIL and a hole transport layer HTL, an organic emission layer including an emission layer EM, and an electron-associated layer including an electron transport layer ETL and an electron injection layer EIL in this order or in reverse order. Although only the hole transport layer HTL, the emission layer EM and the electron transport layer ETL are shown in FIG. 5D, the present disclosure is not limited thereto.

The hole transport layer HTL and the electron transport layer ETL, which are a part of the emission layer EL, may extend to be disposed on the bank layer BNK in the non-active layer.

The cathode CAT is formed on the emission layer EL and the bank layer BNK. The cathode CAT may be formed on an upper surface and a side surface of the emission layer EL to face the anode ANO. The cathode CAT may be formed to have an integrated structure covering the entirety of the active area. The cathode CAT may be electrically connected to the connection electrode 127 through the second contact hole C2 of the bank layer BNK. When the cathode CAT is applied to a top-emission type organic light emitting display apparatus, the cathode CAT may be constituted by a transparent conductive layer made of, for example, indium tin oxide (ITO) or indium zinc oxide (IZO).

In the non-active area, the end of the cathode CAT may overlap with the metal pattern 130.

Meanwhile, as shown in FIG. 6E, in the non-active area, the end of the cathode CAT overlapping with the metal pattern 130 is removed through laser irradiation.

An organic insulating layer pattern 131 is formed on the bank layer BNK to cover the metal pattern 130, the end of the cathode CAT, the second contact hole C2, and an end of the bank layer BNK. The organic insulating layer pattern 131 may include a high-viscosity material. For example, the organic insulating layer pattern 131 may be formed of a non-photosensitive organic insulating material such as acryl resin, epoxy resin, phenolic resin, polyamide resin, polyimide resin, polyethylene or silicon oxycarbide (SiOC), or a photosensitive organic insulating material such as photoreactive acrylic.

An encapsulation layer 120 configured to suppress penetration of moisture is formed on the cathode CAT and the organic insulating layer pattern 131. The encapsulation layer 120 may include a first encapsulation layer 121, a second encapsulation layer 122, and a third encapsulation layer 123 sequentially stacked.

The first encapsulation layer 121 may extend from the active area to the non-active area such that the first encapsulation layer 121 is disposed in both the active area and the non-active area. The first encapsulation layer 121 may extend to a bezel area via the organic insulating layer pattern 131.

The second encapsulation layer 122 may extend from the active area to the non-active area such that the second encapsulation layer 122 is disposed on the first encapsulation layer 121. The second encapsulation layer 122 may extend to an inside of the organic insulating layer pattern 131.

The third encapsulation layer 123 may extend from the active area to the non-active area such that the third encapsulation layer 123 is disposed on the second encapsulation layer 122 and the first encapsulation layer 121. The third encapsulation layer 123 may extend to the bezel area via the organic insulating layer pattern 131.

A temporary protective film 151 may be disposed on the encapsulation layer 120 to extend over the active area and the non-active area, for execution of a subsequent process. The temporary protective film 151 may be removed (peeled off) before execution of the subsequent process.

In addition, as described above, the carrier substrate is removed from the substrate 111, and the temporary protective film 151 is removed (peeled off) before execution of the subsequent process. Thereafter, a polarization plate (not shown), a touch sensor, a cover glass, etc. are sequentially bonded.

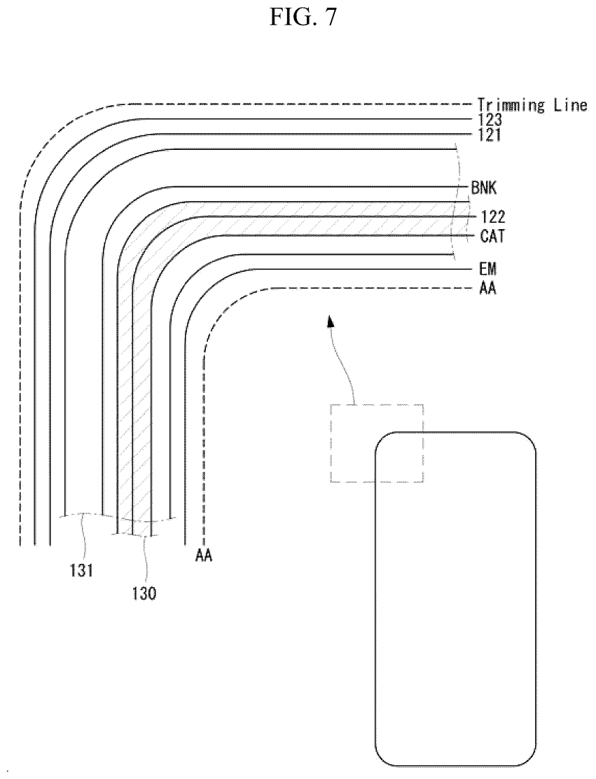

FIG. 7 is a plan view of the display panel in the bezel area according to an example embodiment of the present disclosure.

As shown in FIG. 7, in the display panel according to an example embodiment of the present disclosure, an end of the third encapsulation layer 123, an end of the first encapsulation layer 121, an end of the second encapsulation layer 122, an end of the cathode CAT, and an end of the emission layer EM may be disposed in this order from an outermost side in an inward direction with reference to a trimming line in the bezel area.

In addition, the organic insulating layer pattern 131 may be disposed between the end of the first encapsulation layer 121 and the end of the emission layer EM, and the metal pattern 130 may be disposed on a portion of the bank layer BNK adjacent to the end of the cathode CAT.

Since the end of the cathode CAT overlapping with the metal pattern 130 is removed through laser irradiation, and the organic insulating layer pattern 131 is formed on the bank layer BNK to cover the metal pattern 130, the end of the cathode CAT, the second contact hole C2, and the end of the bank layer BNK, as described above, it may be possible to prevent or suppress an occurrence of a phenomenon in which, when the temporary protective film 151 is removed for execution of a subsequent process, an underlayer is lifted due to removal force applied thereto. In particular, occurrences of failures in the manufacture of the display apparatuses may be reduced because occurrences of a lifting phenomenon of the cathode CAT may be prevented or suppressed.

In addition, the organic insulating layer pattern 131 may function as a dam blocking flow of the second encapsulation layer 122 during formation of the encapsulation layer 120. Accordingly, it may be unnecessary to form a separate dam and, as such, the process may be simplified, and a cell bezel may be reduced. In accordance with a reduction in cell bezel, a narrow bezel may be realized.

Since failures in the manufacture of the display apparatuses are reduced, product costs may be reduced. In addition, environmental/social/governance (ESG) goals enabling a reduction in product costs may be achieved.

Display apparatuses and manufacturing methods thereof according to various example embodiments of the present disclosure may be explained as follows.

A display apparatus according to example embodiments of the present disclosure may include a substrate including an active area configured to display an image and a non-active area disposed around the active area, a thin film transistor disposed on the substrate in the active area, a planarization layer disposed in the active area on the thin film transistor and in the non-active area, the planarization layer having a first contact hole over the thin film transistor, a bank layer disposed in the active area and the non-active area on the planarization layer, the bank layer having an open region in an emission area, a light emitting element disposed on the planarization layer to be connected to the thin film transistor through the first contact hole, and an organic insulating layer pattern disposed on the bank layer in the non-active area to cover an end of a cathode of the light emitting element.

In accordance with an example embodiment of the present disclosure, the display apparatus may further include a metal pattern disposed on the bank layer in the non-active area.

In accordance with an example embodiment of the present disclosure, the metal pattern may be disposed at the end of the cathode.

In accordance with an example embodiment of the present disclosure, the display apparatus may further include a voltage supply line disposed under the planarization layer in the non-active area to supply a voltage, and a connection electrode disposed on the planarization layer in the non-active area. The connection electrode may be electrically connected to the voltage supply line through a second contact hole formed at the planarization layer.

In accordance with an example embodiment of the present disclosure, the cathode of the light emitting element may be connected to the connection electrode through a third contact hole formed at the bank layer in the non-active area.

In accordance with an example embodiment of the present disclosure, the organic insulating layer pattern may cover the end of the cathode, the third contact hole, and an end of the bank layer.

In accordance with an example embodiment of the present disclosure, the display apparatus may further include an encapsulation layer disposed on the cathode and the organic insulating layer pattern.

In accordance with an example embodiment of the present disclosure, the encapsulation layer may include a first inorganic encapsulation layer extending from the active area to the non-active area such that the first inorganic encapsulation layer is disposed in both the active area and the non-active area, the first inorganic encapsulation layer extending to a bezel area via the organic insulating layer pattern, an organic encapsulation layer disposed on the first inorganic encapsulation layer, the organic encapsulation layer extending to an inside of the organic insulating layer pattern in the active area, and a second inorganic encapsulation layer disposed on the organic encapsulation layer, the second inorganic encapsulation layer extending to the bezel area via the organic insulating layer pattern in the active area.

In accordance with an example embodiment of the present disclosure, the organic insulating layer pattern may include a high-viscosity material.

In accordance with an example embodiment of the present disclosure, the organic insulating layer pattern may include a non-photosensitive organic insulating material such as acryl resin, epoxy resin, phenolic resin, polyamide resin, polyimide resin, polyethylene or silicon oxycarbide, or a photosensitive organic insulating material such as photoreactive acrylic.

A method of manufacturing a display apparatus in accordance with example embodiments of the present disclosure may include preparing a substrate including an active area configured to display an image and a non-active area disposed around the active area, forming a thin film transistor on the substrate in the active area, forming a voltage supply line on the substrate in the non-active area, forming a planarization layer on the thin film transistor and the voltage supply line such that the planarization layer has first and second contact holes over the thin film transistor and the voltage supply line, respectively, forming an anode of a light emitting element on the planarization layer such that the anode is connected to the thin film transistor through the first contact hole, forming a connection electrode on the planarization layer such that the connection electrode is connected to the voltage supply line through the second contact hole, forming a bank layer on the planarization layer with the anode and the connection electrode such that the bank layer is provided with an open region over the anode and with a third contact hole over the connection electrode, forming an emission layer on the anode in the open region, forming a cathode on the emission layer and the bank layer such that the cathode is electrically connected to the connection electrode through the third contact hole, and forming an organic insulating layer pattern on the bank layer in the non-active area such that the organic insulating layer pattern covers an end of the cathode, the third contact hole, and an end of the bank layer.

In accordance with an example embodiment of the present disclosure, the method may further include forming a metal pattern between the bank layer and the cathode in the non-active area such that the metal pattern overlaps with the end of the cathode.

In accordance with an example embodiment of the present disclosure, the end of the cathode overlapping with the metal pattern may be removed through laser irradiation.

In accordance with an example embodiment of the present disclosure, the method may further include forming an encapsulation layer on the cathode and the organic insulating layer pattern.

In accordance with an example embodiment of the present disclosure, the encapsulation layer may include a first inorganic encapsulation layer extending from the active area to the non-active area such that the first inorganic encapsulation layer is disposed in both the active area and the non-active area, the first inorganic encapsulation layer extending to a bezel area via the organic insulating layer pattern, an organic encapsulation layer disposed on the first inorganic encapsulation layer, the organic encapsulation layer extending to an inside of the organic insulating layer pattern in the active area, and a second inorganic encapsulation layer disposed on the organic encapsulation layer, the second inorganic encapsulation layer extending to the bezel area via the organic insulating layer pattern in the active area.

In accordance with an example embodiment of the present disclosure, the method may further include bonding a temporary protective film onto the encapsulation layer.

In accordance with an example embodiment of the present disclosure, the method may further include sequentially attaching a polarization plate, a touch sensor, and a cover glass after removing the temporary protective film.

The present disclosure described above is not limited to the above-described example embodiments and the accompanying drawings. Accordingly, it will be understood by those skilled in the art that various substitutions, changes, and modifications may be made without departing from the scope of the disclosure.

What is claimed IS:

1. A display apparatus, comprising:
a substrate comprising an active area configured to display an image and a non-active area disposed around the active area;
a thin film transistor disposed on the substrate in the active area;
a planarization layer disposed in the active area on the thin film transistor and in the non-active area, the planarization layer having a first contact hole over the thin film transistor;
a bank layer disposed in the active area and the non-active area on the planarization layer, the bank layer having an open region in an emission area;
a light emitting element disposed on the planarization layer to be connected to the thin film transistor through the first contact hole; and
an organic insulating layer pattern disposed on the bank layer in the non-active area to cover an end of a cathode of the light emitting element.

2. The display apparatus according to claim 1, further comprising:
a metal pattern disposed on the bank layer in the non-active area.

3. The display apparatus according to claim 2, wherein the metal pattern is disposed at the end of the cathode.

4. The display apparatus according to claim 1, further comprising:
a voltage supply line disposed under the planarization layer in the non-active area to supply a voltage; and
a connection electrode disposed on the planarization layer in the non-active area,
wherein the connection electrode is electrically connected to the voltage supply line through a second contact hole formed in the planarization layer.

5. The display apparatus according to claim 4, wherein the cathode of the light emitting element is connected to the connection electrode through a third contact hole formed in the bank layer in the non-active area.

6. The display apparatus according to claim 5, wherein the organic insulating layer pattern covers the end of the cathode, the third contact hole, and an end of the bank layer.

7. The display apparatus according to claim 1, further comprising:
an encapsulation layer disposed on the cathode and the organic insulating layer pattern.

8. The display apparatus according to claim 7, wherein the encapsulation layer comprises:
a first inorganic encapsulation layer extending from the active area to the non-active area such that the first inorganic encapsulation layer is disposed in both the active area and the non-active area, the first inorganic encapsulation layer extending to a bezel area via the organic insulating layer pattern;
an organic encapsulation layer disposed on the first inorganic encapsulation layer, the organic encapsulation layer extending to an inside of the organic insulating layer pattern in the active area; and
a second inorganic encapsulation layer disposed on the organic encapsulation layer, the second inorganic encapsulation layer extending to the bezel area via the organic insulating layer pattern in the active area.

9. The display apparatus according to claim 1, wherein the organic insulating layer pattern comprises a high-viscosity material.

10. The display apparatus according to claim 9, wherein the organic insulating layer pattern comprises a non-photosensitive organic insulating material such as acryl resin, epoxy resin, phenolic resin, polyamide resin, polyimide resin, polyethylene or silicon oxycarbide, or a photosensitive organic insulating material such as photoreactive acrylic.

11. A method of manufacturing a display apparatus, comprising:
preparing a substrate comprising an active area configured to display an image and a non-active area disposed around the active area;
forming a thin film transistor on the substrate in the active area;
forming a voltage supply line on the substrate in the non-active area;
forming a planarization layer on the thin film transistor and the voltage supply line such that the planarization layer has first and second contact holes over the thin film transistor and the voltage supply line, respectively;
forming an anode of a light emitting element on the planarization layer such that the anode is connected to the thin film transistor through the first contact hole;
forming a connection electrode on the planarization layer such that the connection electrode is connected to the voltage supply line through the second contact hole;
forming a bank layer on the planarization layer with the anode and the connection electrode such that the bank layer is provided with an open region over the anode and with a third contact hole over the connection electrode;
forming an emission layer on the anode in the open region;
forming a cathode on the emission layer and the bank layer such that the cathode is electrically connected to the connection electrode through the third contact hole; and
forming an organic insulating layer pattern on the bank layer in the non-active area such that the organic insulating layer pattern covers an end of the cathode, the third contact hole, and an end of the bank layer.

12. The method according to claim 11, further comprising:
forming a metal pattern between the bank layer and the cathode in the non-active area such that the metal pattern overlaps with the end of the cathode.

13. The method according to claim 12, wherein the end of the cathode overlapping with the metal pattern is removed through laser irradiation.

14. The method according to claim 11, further comprising:
forming an encapsulation layer on the cathode and the organic insulating layer pattern.

15. The method according to claim 14, wherein the encapsulation layer comprises:
a first inorganic encapsulation layer extending from the active area to the non-active area such that the first inorganic encapsulation layer is disposed in both the active area and the non-active area, the first inorganic encapsulation layer extending to a bezel area via the organic insulating layer pattern;
an organic encapsulation layer disposed on the first inorganic encapsulation layer, the organic encapsulation layer extending to an inside of the organic insulating layer pattern in the active area; and
a second inorganic encapsulation layer disposed on the organic encapsulation layer, the second inorganic encapsulation layer extending to the bezel area via the organic insulating layer pattern in the active area.

16. The method according to claim 14, further comprising:
bonding a temporary protective film onto the encapsulation layer.

17. The method according to claim 16, further comprising:
sequentially attaching a polarization plate, a touch sensor, and a cover glass after removing the temporary protective film.

18. The method according to claim 11, wherein the organic insulating layer pattern comprises a non-photosensitive organic insulating material such as acryl resin, epoxy resin, phenolic resin, polyamide resin, polyimide resin, polyethylene or silicon oxycarbide, or a photosensitive organic insulating material such as photoreactive acrylic.
